(19) United States
(12) Patent Application Publication
(10) Pub. No.: US 2004/0107555 A1
(43) Pub. Date: Jun. 10, 2004

(54) Method for making monolithic ceramic capacitor

(76) Inventors: Koji Hattori, Shiga-ken (JP); Teppei Akiyoshi, Shiga-ken (JP)

Correspondence Address: DICKSTEIN SHAPIRO MORIN & OSHINSKY LLP, Edward A. Meilman, 41st Floor, 1177 Avenue of the Americas, New York, NY, 10036-2714, US

(21) Appl. No.: 10/714,977

(22) Filed: Nov. 18, 2003

(30) Foreign Application Priority Data
Nov. 19, 2002 (JP) 2002-334580

(51) Int. Cl. H01G 7/00; H05K 3/02

(52) U.S. Cl. 29/25.42; 29/25.41; 29/846

(57) ABSTRACT

A method for making a monolithic ceramic capacitor ceramic capacitor includes preparing a conductive film on a carrier film by a thin-film forming method; preparing high-binder-content first ceramic green sheets and low-binder-content second ceramic green sheets; transferring the conductive film on a first main surface of the first ceramic green sheet; stacking the second ceramic green sheets on a second main surface of the first ceramic green sheet with the conductive film and stacking another first ceramic green sheet on the second ceramic green sheet so as to form a ceramic green layer; preparing a green composite containing the ceramic green layer; sintering green composite to prepare a compact; and forming external electrodes onto side faces of the compact.

### BACKGROUND OF THE INVENTION

1. Field of the Invention

The present invention relates to a method for making a monolithic ceramic capacitor. In particular, it relates to a method for making a monolithic ceramic capacitor, the dielectric ceramic layers of which are composed of a plurality of ceramic green sheets placed between conductive films.

2. Description of the Related Art

Monolithic ceramic capacitors having dielectric layers made of sintered ceramic between opposing conductor films are increasingly used in various electronic devices.

The dielectric layers of monolithic ceramic capacitors of this type are ceramic layers between internal conductors. Recent developments have reduced the thickness of the dielectric layers to approximately 1 μm to achieve size reduction, higher capacitance and lower costs. Furthermore, the internal conductors are now made of a base metal such as copper or nickel.

In order to increase the capacitance of a monolithic ceramic capacitor, increasing the number of stacked dielectric layers or reducing the thickness of dielectric layers is effective. However, conventional screen-printing methods for making internal conductors from a conductive paste containing conductive powder, an organic binder and an organic solvent have limited capacity for reducing the thickness of the internal conductors. Moreover, thick internal conductors may cause deformation of the composite. In particular, when the number of the stacked dielectric layers is increased, the portion having internal conductors becomes thicker than the portion without internal conductors. In order to prevent deformation of the composite, the thickness of the internal conductors is preferably as small as possible.

However, making thin internal conductors is difficult since the conductive powder in the conductive paste rarely forms a homogeneous film. As a result, the internal conductors become net-like and do not achieve the desired capacitance.

In particular, since the conductive paste contains a conductive powder, an organic binder and an organic solvent, the thickness of the internal conductors before sintering is two to three times that made only from a conductive material.

When the conductive paste is used to form internal conductors, the thickness of the internal conductors after sintering is one half to one third the thickness of the conductive paste before sintering. Merely reducing the thickness of the applied conductive paste before sintering does not form a homogeneous and uniform film after sintering.

As is obvious from the above, there is a limit in reducing the thickness of the internal conductors under the conventional method. In order to overcome this problem, Japanese Unexamined Patent Application Publication Nos. 64-42809 and 6-61090 teach a technique of transferring a metal film onto a ceramic green sheet, the metal film being formed on a base film by a thin-film formation method such as vacuum deposition, sputtering or the like. According to this technique, thin and dense internal conductors can be formed on ceramic green sheets. Moreover, since the internal conductors before sintering are films composed of metal only, the deformation of the composite due to thickness of the internal conductors can be minimized.

The metal film formed by thin-film forming methods disclosed in Japanese Unexamined Patent Application Publication Nos. 64-42809 and 6-61090 is dense, and the internal conductors made from the metal films rarely have defects such as pinholes even when the thickness is reduced to 1 μm or less. Since the metal films formed as such rarely have defects, the metal films inhibit passage of gas generated during pyrolysis of the binder that occurs when the composite is heated to remove the binder. As a result, the binder is insufficiently removed and the internal conductors separate from the ceramic layers, resulting in so-called delamination.

### SUMMARY OF THE INVENTION

An object of the present invention is to provide a method for making a monolithic ceramic capacitor whereby internal conductors are formed by a thin-film forming method to reduce the thickness of dielectric layers without causing interfacial separation between internal conductors and ceramic layers. According to this method, a highly reliable high-performance monolithic ceramic capacitor can be made.

The present inventors conducted extensive investigations and studies and found that the amount of binder needed to bond ceramic green sheets to each other is smaller than the amount of binder needed to bond an internal conductor to a ceramic green sheet. The total amount of the binder can be reduced by preparing a composite with a combination of high-binder-content ceramic green sheets and low-binder-content ceramic green sheets disposed between the high-binder-content ceramic green sheets. In a composite constituted from high-binder-content and low-binder-content ceramic green sheets, the binder can be removed sufficiently and separation of internal conductors from ceramic layers can be prevented.

The present invention, made based on the above-described findings, provides a method for making a monolithic ceramic capacitor including the steps of (a) preparing first ceramic green sheets each having a first main surface provided with a conductive film formed by a thin-film forming method, the first ceramic green sheets composed of a first ceramic material powder and a first binder; (b) sequentially stacking the first ceramic green sheets and second ceramic green sheets to form a green composite, the second ceramic green sheets composed of a second ceramic material powder and a second binder, the second ceramic green sheets being arranged not to come into contact with the first main surfaces of the first ceramic green sheets; and (c) heating the green composite to remove the first binder and the second binder. During step (c), the second binder is removed before the first binder is removed.

According to this method, the internal conductors are prevented from becoming separated from the ceramic layers despite the performance of the binder removal. A highly reliable, high-performance monolithic ceramic capacitor with thinner ceramic layers can be made as a result.

Preferably, the content of the second binder relative to the second ceramic material powder is smaller than the content of the first binder relative to the first ceramic material powder.

More preferably, the first ceramic green sheets with the conductive films are each prepared by transferring the conductive film formed on a carrier film onto the first main surface of the first ceramic green sheet.

Alternatively, the first ceramic green sheets with the conductive films may each be prepared by applying a ceramic slurry composed of the first ceramic material powder and the first binder on the conductive film formed on a carrier film.

Yet alternatively, a first ceramic slurry composed of the first ceramic material powder and the first binder may be applied on the conductive film formed on a carrier film so as to form the first ceramic green sheet, and a second ceramic slurry composed of the second ceramic material powder and the second binder may be applied on the first ceramic green sheet so as to form the second ceramic green sheet.

Still alternatively, the first ceramic slurry may be applied on the conductive film formed on a carrier film so as to form one of the first ceramic green sheets; the second ceramic slurry may be applied on the first ceramic green sheet so as to form the second ceramic green sheet; and the first ceramic slurry may be applied on the second ceramic green sheet so as to form another one of the first ceramic green sheets.

Preferably, the thickness of a dielectric layer disposed between the conductive films is about 0.3 to 1.2 μm. The thin-film forming method may be at least one selected from vacuum vapor deposition, sputtering, electroplating, and electroless plating.

### BRIEF DESCRIPTION OF THE DRAWINGS

FIG. 1 is a cross-sectional view of a monolithic ceramic capacitor made according to a method of the present invention;

FIG. 2 is a flow chart of a method for making a monolithic ceramic capacitor according to a first embodiment of the present invention;

FIGS. 3A to 3E show the steps of making a conductive film;

FIGS. 4A and 4B show the steps of transferring the conductive film onto a ceramic green sheet;

FIG. 5 is a flow chart showing the main steps of a method for making a monolithic ceramic capacitor according to a second embodiment of the present invention;

FIG. 6 shows a step of making a first ceramic green sheet according to the second embodiment;

FIG. 7 is a flow chart showing the main steps of a method for making a monolithic ceramic capacitor according to a third embodiment of the present invention; and

FIG. 8 shows the step of making ceramic green sheets.

### DESCRIPTION OF THE PREFERRED EMBODIMENTS

The preferred embodiments of the present invention will now be described with reference to the drawings.

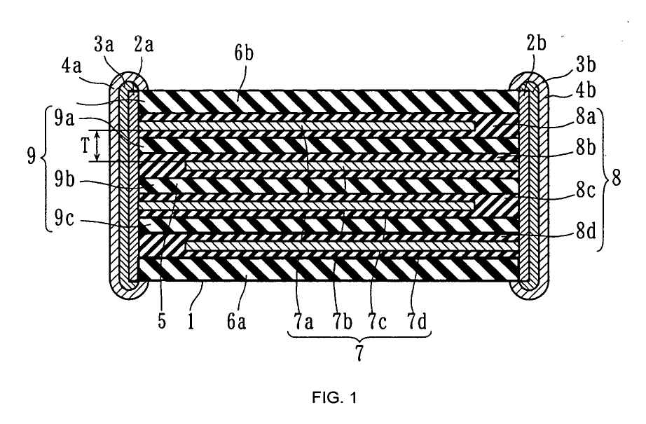

FIG. 1 is a schematic cross-sectional view of an example monolithic ceramic capacitor according the present invention.

The monolithic ceramic capacitor includes a ceramic composite 1 mainly composed of barium titanate (BaTiO₃) and external conductors 2a and 2b, which are composed of a conductive material such as silver and disposed on two side faces of the ceramic composite 1. The external conductors 2a and 2b are respectively plated with first plating films 3a and 3b composed of nickel, copper, a Ni—Cu alloy or the like. The first plating films 3a and 3b are respectively plated with second plating films 4a and 4b composed of a tin or a tin alloy such as solder.

The ceramic composite 1 includes a dielectric block 5, a plurality of internal conductors 7, namely, internal conductors 7a to 7d, and a pair of protective layers 6a and 6b. The dielectric block 5 includes a plurality first dielectric ceramic layers 8, namely, first dielectric ceramic layers 8a to 8d, and a plurality of second dielectric ceramic layers 9, namely, second dielectric ceramic layers 9a to 9c. The first dielectric ceramic layers 8 are in contact with the internal conductors 7a to 7d and the second dielectric ceramic layers 9 are not in contact with the internal conductors 7a to 7d. The layers are stacked in the following order: (from the bottom) the first dielectric ceramic layer 8d, the second dielectric ceramic layer 9c, the first dielectric ceramic layer 8c, the second dielectric ceramic layer 9b, the first dielectric ceramic layer 8b, the second dielectric ceramic layer 9a, and the first dielectric ceramic layer 8a. In this manner, the second dielectric ceramic layers 9a to 9c are prevented from coming into contact with the internal conductors.

Each first dielectric ceramic layer 8 can be made from at least two first ceramic green sheets. Each second dielectric ceramic layer 9 is made from at least one second ceramic green sheet. Two first dielectric ceramic layers 8 and one second dielectric ceramic layer 9 therebetween form a dielectric unit, and the portion of the dielectric unit sandwiched between the internal conductors 9 has a thickness T, i.e., all of the second dielectric ceramic layer 9 and part of the first dielectric ceramic layers 8, is defined as a dielectric layer. As will be described in the later section, the dielectric layer of the present invention is made from a laminate prepared by sequentially stacking at least one first ceramic green sheet, at least one second ceramic green sheet, and another at least one first ceramic green sheet.

The internal conductors 7a and 7d are parallel to each other and extend along the interfaces between a pair of adjacent first dielectric ceramic layers 8. The internal conductors 7a and 7c are electrically connected to the external conductor 2a, and the internal conductors 7b and 7d are electrically connected to the external conductor 2b.

A method for making the monolithic ceramic capacitor shown in FIG. 1 will now be described.

First Embodiment

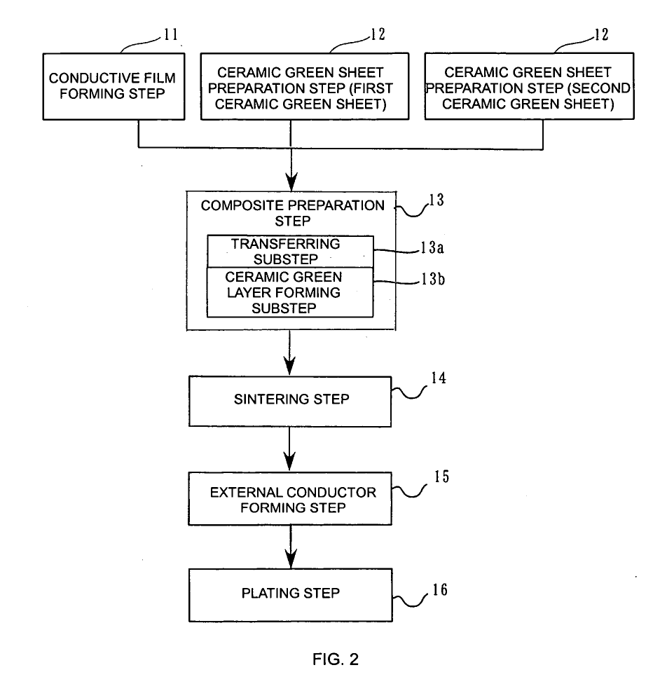

FIG. 2 is a flow chart of a method for making the monolithic ceramic capacitor according to a first embodiment of the present invention.

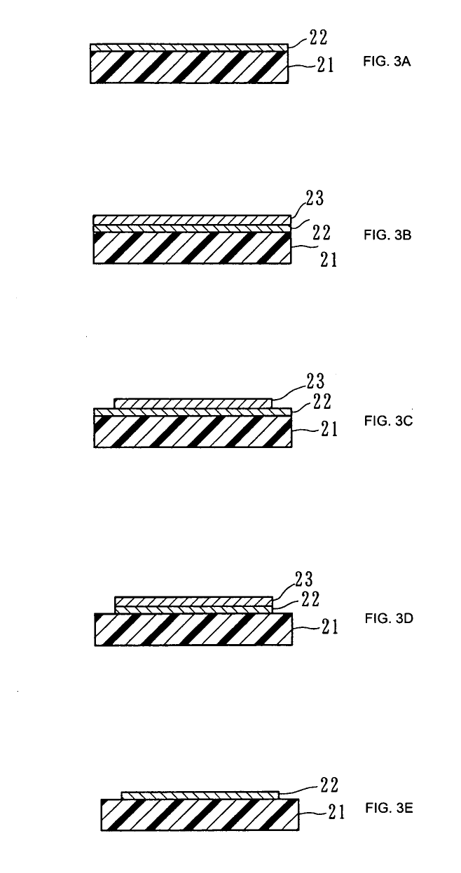

In a conductive film forming step 11, silicone or the like is applied on a surface of a carrier film 21 made of polyethylene terephthalate (PET) or the like to enhance the releasing property of the film. Subsequently, as shown in FIG. 3A, a conductive metal foil film 22 having a thickness of approximately 0.1 μm to approximately 0.8 μm is formed on the carrier film 21 by a thin-film forming method.

Any thin-film forming method may be employed as long as the conductive film 22 can be made in the form of a foil. Examples of the method include vacuum deposition methods, sputtering methods, electroplating methods and autocatalytic electroless plating methods using reductants. The conductive ingredient of the conductive film may be any as long as the resulting conductive film can function as the internal conductor. Examples thereof include platinum, palladium-silver, copper and nickel. Inexpensive nickel is preferred.

The conductive film 22 can be formed by a known photolithographic process and has a predetermined pattern.

In particular, as shown in FIG. 3B, a photoresist 23 is applied on the conductive film 22 and is prebaked. The prebaked photoresist was irradiated with UV light through a photomask (not shown) and developed. The exposed photoresist was post-baked to transfer the photomask pattern onto the photoresist 23, as shown in FIG. 3C.

Portions of the conductive film not covered with the photoresist 23 are etched away, as shown in FIG. 3D. The photoresist 23 is then removed using an organic solvent to form a patterned conductive film 22 on the carrier film 21, as shown in FIG. 3E.

In a ceramic green sheet preparation step 12 (FIG. 2), first and second ceramic green sheets mainly composed of a dielectric such as barium titanate (BaTiO₃) powder but with different binder contents relative to the barium titanate powder are prepared.

In general, the binder contents relative to the ceramic will differ by at least about 5 percentage units and preferably at least about 10 percentage units. For instance, if one binder content is x %, the other binder content will be at least about (x plus 5) percent.

First, the barium titanate powder is prepared by, for example, hydrolysis. In particular, aqueous barium hydroxide and a solution of titanium alkoxide in an organic solvent such as ethyl alcohol, butyl alcohol, isopropyl alcohol or the like, are prepared and mixed such that the molar ratio of barium to titanate (Ba/Ti) becomes a predetermined value. The resulting mixture is charged in a reaction vessel heated to 60 to 100° C. to conduct a synthetic reaction. After about one hour of aging, the reacted mixture was subjected to centrifugal separation to remove the sediment. The sediment was calcined in air at a temperature of 700 to 1,000° C. and pulverized to obtain the barium titanate powder.

The stoichiometric molar ratio of Ba to Ti is 1.000. However, the molar ratio need not be exactly 1.000. The ratio may be adjusted within the range of, for example, 0.950 to 1.050, depending on the intended usage of the capacitor. The molar ratio Ba/Ti is preferably in the range of 1.000 to 1.035 in order to prepare a nonreducing dielectric layer.

A compound containing a rare earth element such as dysprosium, zirconium, manganese, magnesium, silicon or the like, may be added to the barium titanate powder, if necessary. Addition of a sintering aid such as silicon, boron, aluminum, magnesium, lithium or the like, is also preferred.

These additives are preferably in the form of an alkoxide compound, acetylacetonate or a metal soap soluble in the organic solvent since the barium titanate is dispersed in the organic solvent.

When these additives are added to the barium titanate, the organic solvent is removed by evaporation drying or heating after the additives are added.

The barium titanate powder, a binder such as polyvinyl butyl alcohol resin, and an organic solvent such as ethyl alcohol are charged in a ball mill containing a grinding medium of partially stabilized zirconia (PSZ) and are wet-milled for a predetermined time, e.g., 24 hours. Two types of ceramic slurry, i.e., first and second ceramic slurry, having different binder contents are prepared.

When the binder content of all the ceramic green sheets is large, dense and defect-free conductive films obstruct passage of the gas produced due to decomposition of the binder, causing interfacial separation between the internal conductors and the ceramic layers. On the other hand, when the binder content of all the ceramic green sheets is small, adhesion between the conductive films 22 the ceramic green sheets decreases, and the sheets cannot be properly stacked.

Thus, the first ceramic green sheets, which make contact with the conductive films 22, must have a relatively large binder content to obtain sufficient adhesion to the conductive films. Meanwhile, the binder content of the second ceramic green sheets need not be as large since the adhesion between ceramic green sheets composed of the same material is higher than that between the ceramic green sheet and the conductive film.

As the binder burns, holes are formed in the ceramic green sheet in the course of sintering. The rate at which holes are formed is higher in the ceramic green sheets with a higher binder content. Since the ceramic green sheets in contact with the conductive films have a higher binder content, the gas produced due to pyrolysis of the binder can be easily discharged through these holes, thereby preventing the interfacial separation between the internal conductors and the ceramic layers.

In this manner, dense and defect-free ceramic green sheets can be produced with a smaller total amount of the binder. A monolithic ceramic capacitor having an improved reliability can be made as a result.

In this embodiment, the first ceramic green sheets in contact with the conductive films 22 and the second ceramic green sheets not in contact with the conductive films 22 are prepared from separate ceramic slurries having different binder contents, namely, a first ceramic slurry and a second ceramic slurry.

The specific binder contents in the first and second ceramic slurries are adjusted according to the average grain particle diameter of the barium titanate powder and the type of binder, i.e., the adhesive power, the amount of gas produced by pyrolysis, and the like. Ceramic slurries may contain different binders, but the material powder is preferably the same in both the slurries.

Next, in a step 13, a composite constituted from green ceramic layers, which will form dielectric layers, is prepared.

The step 13 includes a transfer substep 13a and a green ceramic layer forming substep 13b. In the transfer substep 13a, the conductive film 22 formed on the carrier film 21 in the step 11 is transferred onto a first main surface of the first ceramic green sheet 24 formed in the step 12.

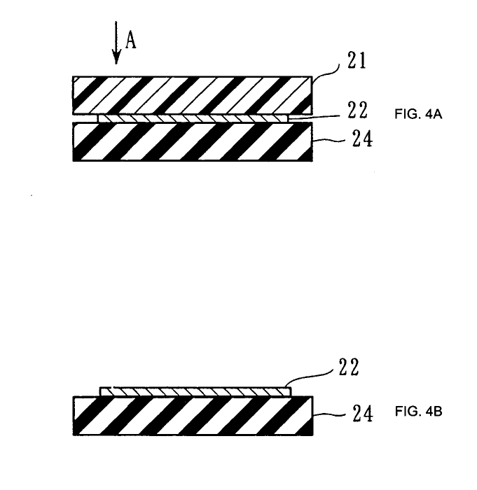

To be more specific, as shown in FIG. 4A, the carrier film 21 is placed on the first ceramic green sheet 24 so that the first ceramic green sheet 24 comes into contact with the conductive film 22. After the carrier film 21 is pressed in the direction of arrow A at a pressure of about 1.96×10⁶ to 4.90×10⁷ Pa at a temperature of, for instance, approximately 100° C., the carrier film 21 is detached, thereby transferring the conductive film 22 onto the first ceramic green sheet 24, as shown in FIG. 4B.

In the subsequent step 13b, a predetermined number of second ceramic sheets are stacked and press-bonded onto a second main surface of the first ceramic green sheet carrying the conductive film 22 on the first main surface, and another first ceramic green sheet is stacked on the surface of the topmost second ceramic green sheet, thereby making a green ceramic layer, which is the precursor of one dielectric layer. One green ceramic layer includes two first ceramic green sheets and a predetermined number of second ceramic green sheets and is provided with a conductive film.

A plurality of green ceramic layers are stacked and press-bonded. Additional first and/or second ceramic green sheets, conductive films, and the like are formed on the stack, as necessary, and the top and the bottom of the resulting stack are covered with an appropriate number of second ceramic green sheets, i.e., the precursors of the protective layers 6a and 6b, so as to prepare a green composite.

As will be described below, the green composite will be baked so that the ceramic material powder will sinter to form dielectric layers. The thickness of the first and second ceramic green sheets is preferably adjusted as such that the thickness T (refer to FIG. 1) of the sintered dielectric layer between conductive films will be within the range of about 0.3 to 1.2 μm.

To be more specific, the minimum combination for preparing the dielectric layer is two first ceramic green sheet and one second ceramic green sheet disposed therebetween. In order to obtain ceramic green sheets with uniform thickness at high accuracy, the thickness of each ceramic green sheet is preferably adjusted so that the thickness is at least about 0.1 μm. Thus, the thickness T of the dielectric layer is preferably at least about 0.3 μm. With the thickness T of the dielectric layer exceeding about 1.2 μm, the resulting monolithic ceramic capacitor rarely has large capacitance since the distance between the conductive films is excessively large. Accordingly, the thickness of the ceramic green sheet is preferably adjusted so that the dielectric layer made therefrom by sintering has a thickness T in the range of about 0.3 to 1.2 μm.

Next, in a step 14, the green composite is heated to a predetermined temperature, e.g., 350° C., in nitrogen atmosphere to remove the binder, and then sintered for approximately two hours at a sintering temperature of about 1,000 to 1,200° C. in a reducing atmosphere to prepare a ceramic composite 1. In particular, during the heating, the binder contained in the second ceramic green sheets is removed first, and then the binder contained in the first ceramic green sheets is removed via the holes formed in the second ceramic green sheets as a result of the binder removal.

In a step 15 of making external conductors, a conductive paste containing a conductive material, such as silver, dispersed in glass frit was applied on the two side faces of the sintered ceramic composite 1. The applied conductive paste is baked to form the external conductors 2a and 2b.

Lastly, in a plating step 16, the first plating films 3a and 3b composed of nickel, copper, a Ni—Cu alloy or the like, and the second plating films 4a and 4b composed of tin or a tin alloy such as solder are formed on the external conductors 2a and 2b to prepare the monolithic ceramic capacitor.

Alternatively, the external conductors may be made by applying the conductive paste on the green composite prior to sintering. In this manner, the ceramic sinter and the external conductors can be made simultaneously.

Since the binder content of the second ceramic green sheets is smaller than that of the first ceramic green sheets, the binder contained in the green composite can be effectively removed in the sintering step 14, thereby preventing the interfacial separation between the internal conductors 7 and the first ceramic green sheets 8.

Second Embodiment

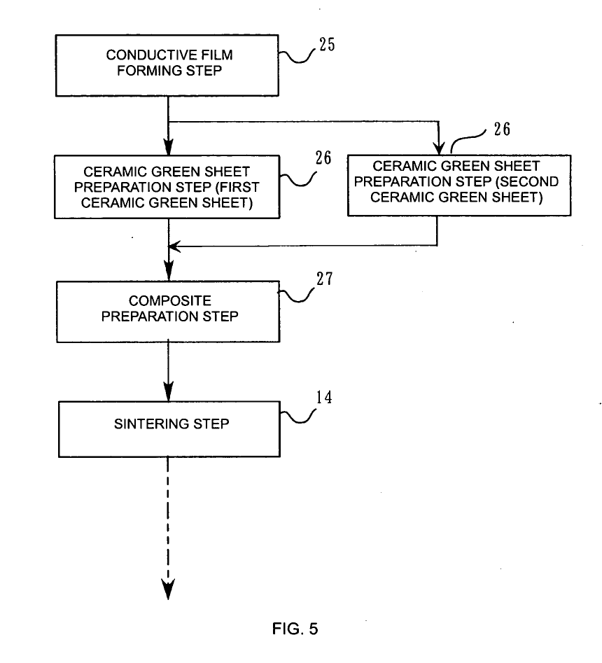

FIG. 5 is a flow chart showing the main steps of a method for making a monolithic ceramic capacitor according to a second embodiment of the present invention. In this embodiment, the first ceramic green sheet is made directly on the conductive film disposed on the carrier film.

In particular, a conductive film 29 is formed on a carrier film 28 in a conductive film forming step 25 as in the first embodiment.

In a ceramic green sheet preparing step 26, first and second ceramic slurries having different binder contents are prepared as in the first embodiment.

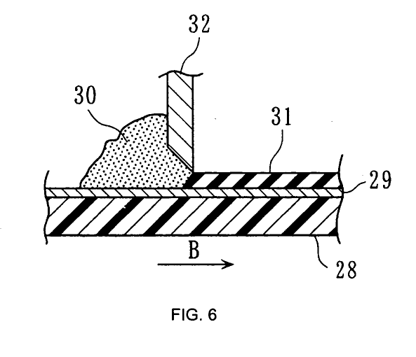

Then, as shown in FIG. 6, a first ceramic slurry 30 is supplied onto the conductive film 29 on the carrier film 28 traveling in the direction of arrow B. Using a blade 32, the first ceramic slurry 30 is shaped to have a predetermined thickness so as to form a first ceramic green sheet 31 directly on the conductive film 29.

Next, the second ceramic slurry is shaped by a doctor blade method so as to make a second ceramic green sheet having a binder content lower than that of the first ceramic green sheet. Another first ceramic green sheet is prepared from the first ceramic slurry by a doctor blade method.

In a composite making step 27, the second ceramic green sheet is press-bonded onto the first ceramic green sheet 31, and another first ceramic green sheet is press-bonded onto the second ceramic green sheet so as to make a stack of ceramic green sheets and the carrier film 29 is removed.

A predetermined number of the laminate units formed as above are stacked. An appropriate number of the second ceramic green sheets are stacked on the top and the bottom of the resulting stack so as to form the protective layers 6a and 6b. As a result, the green composite is made.

Subsequently, the same steps as in the first embodiment, i.e., the steps 14, 15, and 16 are performed to make the monolithic ceramic capacitor.

In this embodiment also, the binder content of the second ceramic green sheets is smaller than that of the first ceramic green sheets. Thus, the binder contained in the green composite can be effectively removed in the sintering step 14 without degrading the adhesiveness between the conductive film 29 and the first ceramic green sheet 31, and the interfacial separation between the internal conductor 7 and the first dielectric ceramic layer 8 can be avoided.

Since the first ceramic green sheet 31 is directly formed on the conductive film 29 in the second embodiment, the transfer step is no longer needed and the manufacturing process can be simplified.

Third Embodiment

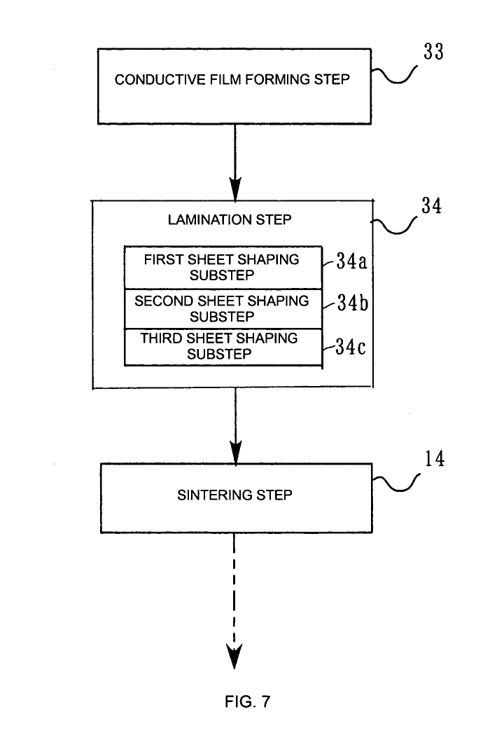

FIG. 7 is a flow chart showing the main steps of a method for making a monolithic ceramic capacitor according to a third embodiment of the present invention. The method of the third embodiment includes a lamination step 34 that replaces both the ceramic green sheet making step and the composite making step. In the lamination step 34, first and second ceramic green sheets are consecutively laminated on the conductive film formed on a carrier film to prepare a green composite.

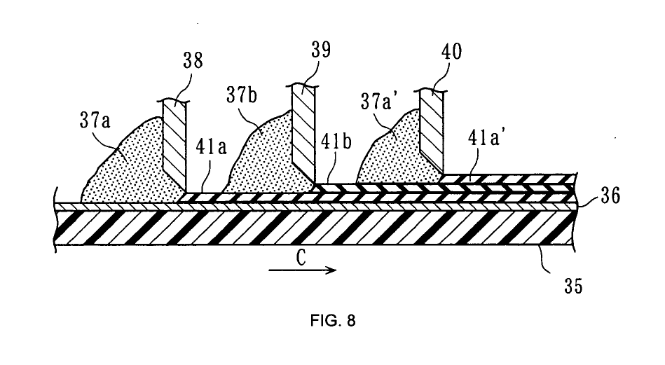

In particular, a conductive film 36 is formed on a carrier film 35 as in the first and second embodiments, as shown in FIG. 8.

In the lamination step 34, the first ceramic slurry and the second ceramic slurry having a binder content smaller than that of the first ceramic slurry are prepared as in the first embodiment.

In a first sheet shaping substep 34a, as shown in FIG. 8, a first ceramic slurry 37a is supplied onto the conductive film 36 on the carrier film 35 traveling in the direction of arrow C. Using a blade 38, the first ceramic slurry 37a is formed into a first ceramic green sheet 41a having a predetermined thickness on the conductive film 36.

In a subsequent second sheet shaping substep 34b, a second ceramic slurry 37b is supplied onto the first ceramic green sheet 41a. Using a blade 39, the second ceramic slurry 37b is shaped into a second ceramic green sheet 41b having a predetermined thickness on the first ceramic green sheet 41a.

In a third sheet shaping substep 34c, a first ceramic slurry 37a′ is supplied onto the second ceramic green sheet 41b. Using a blade 40, the first ceramic slurry 37a′ is shaped into a first ceramic green sheet 41a′ having a predetermined thickness on the second ceramic green sheet 41b.

The ceramic green sheets including those with conductive films prepared as above and from which the carrier film 35 has been removed are press-bonded to form a stack, and an adequate number of second ceramic green sheets are provided on the top and the bottom of the stack to form the protective layers 6a and 6b so as to form a green composite.

Subsequently, the same steps as in the first embodiment, i.e., the steps 14, 15, and 16 are performed to prepare the monolithic ceramic capacitor.

In this embodiment also, the binder content of the second ceramic green sheets is smaller than that of the first ceramic green sheets. Thus, the binder contained in the green composite can be effectively removed in the sintering step 14 without degrading the adhesiveness between the conductive film 36 and the first ceramic green sheet 41 and 41a′, and the interfacial separation between the internal conductor 7 and the first dielectric ceramic layer 8 can be avoided.

In the third embodiment, since the first and second ceramic green sheets 41a, 41b, and 41a′ are directly and consecutively formed on the conductive film 33, the manufacturing process can be simplified further.

It should be understood that the scope of the present invention is not limited to the above preferred embodiments. In particular, the conductive film 22 may be formed by a technique other than the photolithography. For example, a conductive film having a predetermined pattern may be prepared by forming a conductive film on a carrier film, forming a patterned resist layer by screen printing or the like on the conductive film, removing portions of the conductive film not covered with the resist layer by an acidic solution such as nitric acid, and removing the resist layer with an organic solvent.

Moreover, the barium titanate powder, i.e., the ceramic material powder, may be made by a hydrothermal crystallization method, a solid phase method, or the like instead of hydrolysis.

### EXAMPLES

The present invention will now be described by way of EXAMPLES.

### Preparatory Example 1

A copper thin film was vacuum-deposited on a carrier film composed of polyethylene terephthalate (PET) subjected in advance to a releasing treatment. A nickel thin film was formed on the copper thin film by electroplating. Subsequently, the thin films were subjected to a known photolithographic method (refer to FIG. 3) described in the above embodiments so as to form a patterned conductive film having a thickness of 0.1 to 0.8 μm.

A barium hydroxide aqueous solution prepared by dissolving barium hydroxide octahydrate in 90° C. deionized water, and a titanium isopropoxide solution in isopropyl alcohol were prepared.

The barium hydroxide aqueous solution was blended with the titanium isopropoxide solution such that the molar ratio of barium to titanium (Ba/Ti) was 1.002. The mixture was charged in a reaction vessel heated to 80° C. to initiate the synthetic reaction. After an hour of aging, the mixture was centrifuged to separate crystals. The crystals were calcined in air at 700 to 1,000° C. and pulverized to prepare a calcined powder.

The calcined powder was dispersed in ethyl alcohol. Alkoxide compounds of dysprosium, magnesium, manganese and barium, and a sintering aid, i.e., an alkoxide compound mainly composed of Si—B, were added to the dispersion to prepare a slurry. The slurry was dried and heated to remove ethyl alcohol. Two barium titanate powders having an average grain size of 50 nm and 80 nm, respectively, were prepared.

The barium titanate powder, a binder, i.e., polyvinyl butyl alcohol resin, and ethyl alcohol were charged in a ball mill containing PSZ. Wet-milling was performed for 24 hours to prepare a ceramic slurry. Here, a plurality ceramic slurries with different binder contents were prepared.

To be more specific, four ceramic slurries were prepared by mixing 100 parts by weight of each barium titanate powder with 15 parts by weight or 5 parts by weight of the binder. The barium titanate powder having an average grain size of 50 nm is shaped into a 0.15 μm sheet by a doctor blade method, and the barium titanate powder having an average grain size of 80 μm was shaped into a 0.30 μm sheet by a doctor blade method so as to prepare ceramic green sheets A to D.

Furthermore, 100 parts by weight of a barium titanate powder having an average particle size of 180 nm was mixed with 8 parts by weight of binder, and the mixture was formed into a 1.00 μm sheet as in above to prepare a ceramic green sheet E.

TABLE 1

| | Average grain size | | |
|---|---|---|---|
| Ceramic green | of material powder | Binder content | Sheet thickness |
| sheet | (nm) | (parts by weight) | (μm) |
| A | 50 | 15 | 0.15 |
| B | 50 | 5 | 0.15 |
| C | 80 | 15 | 0.30 |
| D | 80 | 5 | 0.30 |
| E | 180 | 8 | 1.00 |

Monolithic ceramic capacitors of EXAMPLES 1 to 7 and COMPARATIVE Examples 1 to 7 were prepared from combinations of the ceramic green sheets A to E.

### Example 1

The ceramic green sheet A was used as the first ceramic green sheet. A patterned conductive film was transferred onto the surface of the ceramic green sheet A to form an internal conductor having a thickness of 0.1 μm according to the process described in the preferred embodiment.

The ceramic green sheet B was used as the second ceramic green sheet. An appropriate number of ceramic green sheets A with internal conductors and an appropriate number of ceramic green sheet B were stacked to form a stack having five green ceramic layers, which were the precursors of dielectric layers. During the course of forming the stack, the ceramic green sheets were stacked such that ends of internal conductors alternately appear on the two side faces of the stack. The stack was then sandwiched by an appropriate number of second ceramic green sheets to form a green composite.

The green composite was baked at 350° C. in nitrogen atmosphere to remove the binder and then sintered at 1,150° C. in reducing atmosphere containing H₂—N₂—H₂O gas at an oxygen partial pressure of 10⁻⁹ to 10⁻¹² MPa for two hours to obtain a ceramic compact.

A conductive paste containing silver, which was the main component, and a B₂O₃—Li₂O—SiO₂—BaO glass frit was applied on two side faces of the ceramic compact. The applied paste was baked at 600° C. in nitrogen atmosphere to form external conductors. A monolithic ceramic capacitor 5.0 mm in length, 5.7 mm in width and 2.4 mm in thickness was prepared. The area of the internal conductors overlapping each other was 16.3×10⁻⁶ m² per dielectric layer.

### Example 2

A monolithic ceramic capacitor was made as in EXAMPLE 1 except that two ceramic green sheets B were stacked on the ceramic green sheet A.

### Example 3

A monolithic ceramic capacitor was made as in EXAMPLE 1 except that the ceramic green sheet C was used as the first ceramic green sheet, the ceramic green sheet D was used as the second ceramic green sheet, and the thickness of the internal conductor was 0.2 μm.

### Example 4

A monolithic ceramic capacitor was made as in EXAMPLE 3, except that two ceramic green sheets D were stacked on the ceramic green sheet C.

### Example 5

A monolithic ceramic capacitor was made as in EXAMPLE 3, except that four ceramic green sheets D were stacked on the ceramic green sheet C.

### Example 6

A monolithic ceramic capacitor was made as in EXAMPLE 3, except that four ceramic green sheets D were stacked on the ceramic green sheet C and that the thickness of the internal conductor was 0.4 μm.

### Example 7

A monolithic ceramic capacitor was made as in EXAMPLE 3, except that six ceramic green sheets D were stacked on the ceramic green sheet C and that the thickness of the internal conductor was 0.8 μm.

### Comparative Example 1

A monolithic ceramic capacitor was prepared using only the ceramic green sheets A. In particular, a conductive film having a thickness of 0.1 μm was transferred onto each of the two main surfaces of a ceramic green sheet A so as to form one green ceramic layer, i.e., the precursor of a dielectric layer. Next, another ceramic green sheet A, one main surface of which is provided with a conductive film having a thickness of 0.1 μm, was stacked on the aforementioned ceramic green sheet A, and this process was repeated to form a stack having five green ceramic layers. The stack was sandwiched by an appropriate number of ceramic green sheets A to form a green composite. During the course of preparing the composite, The ceramic green sheets were stacked such that the internal conductors alternately appeared in the side faces of the stack and the bottom and the top of the stack were covered with an appropriate number of ceramic green sheets A.

Using the green composite, a monolithic ceramic capacitor was made according to the process described in each EXAMPLE.

### Comparative Example 2

Another monolithic ceramic capacitor was prepared using only the ceramic green sheets A. In particular, a 0.1 μm conductive film was transferred onto a first main surface of a ceramic green sheet A to form an internal conductor. Another ceramic green sheet A without conductive film was stacked on a second main surface of this ceramic green sheet A. This process was repeated until a stack of five precursors of dielectric layers was formed. Subsequently, a monolithic ceramic capacitor was prepared from the green composite according to the method described in EXAMPLES above.

### Comparative Example 3

A monolithic ceramic capacitor was prepared using only the ceramic green sheets C. In particular, a conductive film was having a thickness of 0.2 μm was transferred onto a first main surface of a ceramic green sheet C to form an internal conductor. Two ceramic green sheets C without internal conductors were stacked on a second first main surface of the aforementioned sheet having the internal conductor. This process was repeated until a stack of five precursors of dielectric layers was formed. During the course, ceramic green sheets were stacked such that the internal conductors alternately appeared in the side faces of the stack. The bottom and the top of the resulting stack were covered with an appropriate number of ceramic green sheets C to prepare a green composite. Subsequently, a monolithic ceramic capacitor was prepared from the green composite according to the method described in EXAMPLES above.

### Comparative Example 4

A monolithic ceramic capacitor was prepared as in COMPARATIVE EXAMPLE 3 except that the thickness of the internal conductor was changed to 0.4 μm and that the number of the ceramic green sheets C without internal conductors stacked on the ceramic green sheet C with the internal conductor were changed to six.

### Comparative Example 5

An attempt was made to use the ceramic green sheets D in this COMPARATIVE EXAMPLE to prepare a monolithic ceramic capacitor as in COMPARATIVE EXAMPLE 3. However, the conductive film did not transfer to the ceramic green sheets, and the monolithic ceramic capacitor was thus not made.

The reason for failure to transfer the conductive film onto the ceramic green sheet is presumably because the binder content of the ceramic green sheets D was excessively small, i.e., 5 parts by weight relative to 100 parts by weight of barium titanate, and the adhesiveness of the conductive film to the ceramic green sheet was insufficient as a result.

### Comparative Example 6

A monolithic ceramic capacitor was prepared as in COMPARATIVE Example 1 except that the thickness of the internal conductor was changed to 0.4 μm, and the ceramic green sheets E were used instead of the ceramic green sheets A.

### Comparative Example 7

A monolithic ceramic capacitor was made as in COMPARATIVE EXAMPLE 6 except that two ceramic green sheets E were used to constitute one dielectric layer precursor and that the thickness of the internal conductor was changed to 0.8 μm.

Five samples of monolithic ceramic capacitors of each of EXAMPLES and COMPARATIVE EXAMPLES described above were examined with a metallurgical microscope (magnification: 50×). In particular, the samples were embedded in resin and were polished so that junctions between the conductors and the ceramics, i.e., whether there was interfacial separation, could be visually examined.

Table 2 shows the specifications of each ceramic layer, i.e., the dielectric layer precursor, transferability of the conductive film, and occurrence of the interfacial separation.

TABLE 2

| | Specification of precursor | | | | | | | | |
|---|---|---|---|---|---|---|---|---|---|
| | Sheet structure between conductive films (internal | | | | | | | | |
| | conductors) | | | | | | Thickness | | |
| | First Sheet | | Second sheet | | First sheet | | of | Transferability | |
| | (upper side) | | (intermediate) | | (lower side) | | conductive | of | |
| | Sheet | No. of | Sheet | No. of | Sheet | No. of | film | conductive | Interfacial |
| | Type | sheets | Type | sheets | Type | sheets | (μm) | film* | separation |
| Ex*. 1 | A | 1 | B | 1 | A | 1 | 0.1 | Y | None |
| Ex. 2 | A | 1 | B | 2 | A | 1 | 0.1 | Y | None |
| Ex. 3 | C | 1 | D | 1 | C | 1 | 0.2 | Y | None |
| Ex. 4 | C | 1 | D | 2 | C | 1 | 0.2 | Y | None |
| Ex. 5 | C | 1 | D | 4 | C | 1 | 0.2 | Y | None |
| Ex. 6 | C | 1 | D | 4 | C | 1 | 0.4 | Y | None |
| Ex. 7 | C | 1 | D | 6 | C | 1 | 0.8 | Y | None |

| | | | | |
|---|---|---|---|---|
| C. EX*. 1 | A × 1 | 0.1 | Y | Observed |
| C. Ex. 2 | A × 2 | 0.1 | Y | Observed |
| C. Ex. 3 | C × 3 | 0.2 | Y | Observed |
| C. Ex. 4 | C × 8 | 0.4 | Y | Observed |
| C. Ex. 5 | D × 3 | 0.2 | N | — |
| C. Ex. 6 | E × 1 | 0.4 | Y | None |
| C. Ex. 7 | E × 2 | 0.8 | Y | None |

Ex.: EXAMPLE;
C. Ex.: COMPARATIVE EXAMPLE
Y: Conductive film was transferred onto the green sheet
N: Conductive film was not transferred onto the green sheet

As is apparent from Table 2, the monolithic ceramic capacitors of COMPARATIVE EXAMPLES 1 to 4, which were made from green ceramic layers having a high binder content, i.e., 15 parts by weight relative to 100 parts by weight of barium titanate powder, exhibited satisfactory conductive film transferability; however, the conductive films obstructed the escape of the gas produced by the pyrolysis during binder removal, resulting in inefficient binder removal and interfacial separation.

COMPARATIVE EXAMPLES 6 and 7 exhibited sufficient transferability since the binder content thereof is relatively large, i.e., 8 parts by weight relative to 100 parts by weight of barium titanate. Moreover, no interfacial separation occurred. However, they had poor durability, as described below, which degraded the reliability.

As is previously described, in EXAMPLES 1 to 7, the binder content of the ceramic green sheets in contact with the conductive film was 15 parts by weight, which was high enough to achieve excellent transferability. Since the binder content of the ceramic green sheets not in contact with the conductive film was 5 parts by weight, the gas produced by thermal decomposition of the binder could be easily discharged through the holes formed by removal of the binder. Thus, the binder in the green composite can be efficiently removed, and the interfacial separation can be prevented.

The samples of EXAMPLES 1 to 7 and COMPARATIVE EXAMPLE 6, which exhibited satisfactory conductive film transferability and prevented interfacial separation, were further examined as to the average grain size of the sintered ceramic the thickness T of the dielectric layer, dielectric constant ε, dielectric loss tan δ, and resistivity ρ. The samples of EXAMPLE 7 and COMPARATIVE EXAMPLE 6 were further subjected to a high-temperature load test to examine the reliability.

A polished cross-section of the sintered ceramic was etched, and the average grain size of the ceramic sinter was observed with a scanning electron microscope (SEM).

The thickness T of the dielectric layer was determined with the SEM.

The capacitance C and the dielectric loss tan δ were determined by an automatic bridge measurement. The dielectric constant ε was calculated from the results.

The resistivity ρ was determined based on insulation resistance R measured with an insulating-resistance tester by applying a 5-V DC voltage for two minutes at 25° C.

In the high-temperature load test, durability was examined by measuring the time for the insulation resistance R to decrease to 10⁵ Ω or lower at a 5-V DC voltage at 150° C. in several samples and by averaging the time. The results are shown in Table 3.

TABLE 3

| | | | | Dielectric characteristics | | | |
|---|---|---|---|---|---|---|---|
| | | Average grain | Thickness of | Dielectric | Dielectric | | High |
| | | size of sinter | dielectric | constant ∈ | loss tan δ | Resistivity ρ | temperature |
| | | (nm) | layer | (−) | (%) | (Ω·cm) | load test |
| Ex. | 1 | 88 | 0.3 | 1780 | 5.4 | 12.4 | — |
| | 2 | 90 | 0.4 | 1800 | 3.4 | 13.0 | — |
| | 3 | 98 | 0.6 | 1820 | 2.9 | 13.1 | — |
| | 4 | 101 | 0.8 | 1820 | 3.0 | 13.1 | — |
| | 5 | 100 | 1.2 | 1820 | 3.1 | 13.1 | — |
| | 6 | 99 | 1.2 | 1820 | 3.0 | 13.1 | — |
| | 7 | 102 | 1.6 | 1830 | 3.2 | 13.2 | 92 |
| C. Ex. | 6 | 188 | 0.8 | 2200 | 3.4 | 12.9 | 64 |
| | 7 | 191 | 1.6 | 2240 | 3.6 | 13.3 | — |

Ex.: EXAMPLE;
C. Ex.: COMPARATIVE EXAMPLE

Table 3 shows that COMPARATIVE EXAMPLE 6 exhibited a satisfactory dielectric constant ε, dielectric loss tan δ and resistivity ρ, but lower reliability compared to EXAMPLE 7. While the thickness of the ceramic green sheet of COMPARATIVE EXAMPLE 6 was large enough, i.e., 1.00 μm, to prevent the interfacial separation despite the low binder content, the average grain size of the baruim titanate material powder was large, i.e., 180 nm, thereby causing defects in the ceramic green sheets and degradation in reliability.

In contrast, samples of EXAMPLES 1 to 7 all exhibited superior dielectric characteristics and had a smaller average grain size, i.e., 50 nm or 80 nm, and a smaller sheet thickness, i.e., 0.15 μm or 0.30 μm, in comparison with COMPARATIVE EXAMPLES 6 and 7. The monolithic ceramic capacitors of EXAMPLES 1 to 7 had superior mechanical strength, durability and reliability in addition to superior dielectric characteristics.

### Preparatory Example 2

A barium titanate powder having an average grain size of 80 nm was prepared as in PREPARATORY EXAMPLE 1. A first ceramic slurry was prepared by blending 100 parts by weigh of the barium titanate powder with 15 parts by weight of a binder, and a second ceramic slurry was prepared by blending 100 parts by weigh of the barium titanate powder with 5 parts by weight of a binder.

The second ceramic slurry was shaped by a doctor blade method so as to prepare a predetermined number of second ceramic green sheets having a thickness of 0.30 μm.

A patterned conductive film 0.2 μm in thickness was formed on a carrier film as in PREPARATORY EXAMPLE 1. A first ceramic slurry was fed onto the conductive film and was shaped by a doctor blade method so as to realize a predetermined number of first ceramic green sheets on the conductive film.

Next, the first ceramic green sheets and the second ceramic green sheet were stacked so that the second ceramic green sheet was sandwiched by conductive-film-free surfaces of the first ceramic green sheets and the carrier film removed. The first ceramic green sheets and the second ceramic green sheet therebetween form a green ceramic layer, i.e., the precursor of a dielectric layer.

The second ceramic green sheets and the first ceramic green sheets were adequately stacked to prepare a stack having five green ceramic layers. A predetermined number of additional second ceramic green sheets were stacked on the top and the bottom of the stack to prepare a green composite.

A monolithic ceramic capacitor of EXAMPLE 11 was prepared from the green composite as in PREPARATORY EXAMPLE 1.

Using only the second slurry (binder content: 5 parts by weight), an attempt was made to prepare a monolithic ceramic capacitor as in EXAMPLE 11. However, it was not possible to form a conductive film on the first ceramic green sheet because the first ceramic green sheet had an excessively low binder content.

Table 4 shows the specifications of the green ceramic layers of EXAMPLE 11 and COMPARATIVE EXAMPLE 11, formability of the conductive film and the occurrence of the interfacial separation.

TABLE 4

| | Specifications of green ceramic layer | | | | | | | | |
|---|---|---|---|---|---|---|---|---|---|
| | Sheet structure between conductive films (internal conductors) | | | | | | | | |
| | First sheet | | Second sheet | | First sheet | | | | |
| | (upper side) | | (intermediate) | | (lower side) | | | | |
| | Binder | | Binder | | Binder | | | | |
| | content | Sheet | content | Sheet | content | Sheet | Thickness of | | |
| | (parts by | thickness | (parts by | thickness | (parts by | thickness | conductive film | Formability of | Interfacial |
| | weight) | (μm) | weight) | (μm) | weight) | (μm) | (μm) | conductive film | separation |
| Ex. 11 | 15 | 0.3 | 5 | 0.3 | 15 | 0.3 | 0.2 | Y | None |
| C. Ex. 11 | 5 | 0.3 | 5 | 0.3 | 5 | 0.3 | 0.2 | N | — |

Ex.: EXAMPLE;
C. Ex.: COMPARATIVE EXAMPLE
Y: Conductive film was formed onto the green sheet
N: Conductive film was not formed onto the green sheet

Table 4 shows that in EXAMPLE 11, the conductive film was properly formed on the ceramic green sheet and interfacial separation did not occur.

Next, as in PREPARATORY EXAMPLE 1, the average grain size of the sinter, the thickness T of the dielectric layer, the dielectric constant ε, the dielectric loss tan δ and the resistivity ρ were measured. The results are shown in Table 5.

TABLE 5

| | Average | | Dielectric characteristics | | |
|---|---|---|---|---|---|
| | grain size | Thickness T | Dielectric | Dielectric | Resis- |
| | of sinter | of dielectric | constant ∈ | loss tan δ | tivity ρ |
| | (nm) | layer | (−) | (%) | (Ω · cm) |
| Ex. 11 | 100 | 0.6 | 1820 | 3.0 | 13.1 |
| C. Ex. 11 | — | — | — | — | — |

Ex.: EXAMPLE;
C. Ex.: COMPARATIVE EXAMPLE

As is obvious from Table 5, EXAMPLE 11 exhibited superior dielectric characteristics.

### Preparatory Example 3

A first and second ceramic slurries were prepared as in PREPARATORY EXAMPLE 2.

Next, a patterned conductive film 0.2 μm in thickness was formed on a carrier film as in PREPARATORY EXAMPLE 2. The first ceramic slurry, the second ceramic slurry, and once again the first ceramic slurry were sequentially applied on the conductive film to prepare a green ceramic layer having a thickness of 0.9 μm. A stack having five green ceramic layers so made were stacked after removal of the cover film. Using the resulting stack, a monolithic ceramic capacitor of EXAMPLE 21 was made as in PREPARATORY EXAMPLE 1.

Using only the ceramic slurry containing 15 parts by weight of binder relative to 100 parts by weight of the barium titanate, a monolithic ceramic capacitor of COMPARATIVE EXAMPLE 21 was prepared as above.

An attempt was made to prepare a monolithic ceramic capacitor of COMPARATIVE EXAMPLE 22 using the ceramic slurry containing 5 parts by weight of binder relative to 100 parts by weight of barium titanate. However, it was not possible to form a first ceramic green sheet on the conductive layer because of the low binder content.

Next, the occurrence of interfacial separation was examined as to EXAMPLE 21 and COMPARATIVE EXAMPLES 21 and 22 by the same process as in Preparatory Example 1. The results and the specifications of the green ceramic layers are shown in Table 6.

TABLE 6

| | Specifications of green ceramic layer | | | | | | | | |
|---|---|---|---|---|---|---|---|---|---|
| | Sheet structure between conductive films (internal conductors) | | | | | | | | |
| | First sheet | | Second sheet | | First sheet | | | | |
| | (upper side) | | (intermediate) | | (lower side) | | | | |
| | Binder | | Binder | | Binder | | | | |
| | content | Sheet | content | Sheet | content | Sheet | Thickness of | | |
| | (parts by | thickness | (parts by | thickness | (parts by | thickness | conductive film | Formability of | Interfacial |
| | weight) | (μm) | weight) | (μm) | weight) | (μm) | (μm) | conductive film | separation |
| Ex. 21 | 15 | 0.3 | 5 | 0.3 | 15 | 0.3 | 0.2 | Y | None |
| C. Ex. 21 | 15 | 0.3 | 15 | 0.3 | 15 | 0.3 | 0.2 | Y | Occurred |
| C. Ex. 22 | 5 | 0.3 | 5 | 0.3 | 5 | 0.3 | 0.2 | N | — |

Ex.: EXAMPLE;
C. Ex.: COMPARATIVE EXAMPLE
Y: Conductive film was formed onto the green sheet
N: Conductive film was not formed onto the green sheet

As is apparent from Table 6, the gas produced by pyrolysis of the binder was obstructed by the conductive film, and interfacial separation occurred as a result in COMPARATIVE EXAMPLE 21 having a high binder content.

In contrast, in EXAMPLE 21 having high-binder-content first ceramic green sheets and low-binder-content second ceramic green sheets, the conductive film was properly formed on the ceramic green sheet, and no interfacial separation occurred.

Next, as in PREPARATORY EXAMPLE 1, the average grain size of the sinter, the thickness T of the dielectric layer, the dielectric constant c, the dielectric loss tan δ and the resistivity ρ were measured. The results are shown in Table 7.

TABLE 7

| | Average | | Dielectric characteristics | | |
|---|---|---|---|---|---|
| | grain size | Thickness T | Dielectric | Dielectric | |
| | of sinter | of dielectric | constant ∈ | loss tan δ | Resistivity |
| | (nm) | layer | (−) | (%) | ρ (Ω· cm) |
| Ex. 21 | 99 | 0.6 | 1820 | 3.1 | 13.2 |
| C. Ex. 21 | — | — | — | — | — |
| C. Ex. 22 | — | — | — | — | — |

Ex.: EXAMPLE;
C. Ex.: COMPARATIVE EXAMPLE

As is apparent from Table 7, EXAMPLE 21 exhibited superior dielectric characteristics.

According to the method for making the monolithic ceramic capacitor of EXAMPLES, the binder can be efficiently removed by heating and interfacial separation between the first ceramic green sheets and the conductive films can be prevented. This is because the binder content of the second ceramic green sheets is lower than that of the first ceramic green sheets.

Thus, according to the method of the present invention, interfacial separation between the internal conductors and the ceramic layers does not occur by heating the composite. A monolithic ceramic capacitor with high mechanical strength, high reliability, and excellent dielectric characteristics can be this made.

Various changes and modifications can be made in the process and products of this invention without departing from the spirit and scope thereof the various embodiments described herein were for the purpose of illustration only and were not intended to limit the invention.

What is claimed is:

1. A method for making a monolithic ceramic capacitor, comprising:
(a) providing a pair of first ceramic green sheets and at least one second ceramic green sheet, each of the first ceramic green sheets having a first main surface provided with a thin-film conductive film, each of the first and second ceramic green sheets comprising a ceramic material and a binder, wherein the binder or the amount thereof in the second ceramic green sheet is such that the removal upon heating of the second ceramic green sheet binder commences before that of the first ceramic green sheet binder;
(b) forming a green composite stack in which the second ceramic green sheet is disposed between the two first ceramic green sheets so as not to come into contact with the first main surfaces of the first ceramic green sheets; and
(c) heating the green composite to remove the first binder and the second binder.

2. The method according to claim 1, wherein the content of binder relative to the ceramic is larger in the first ceramic green sheets than in the second ceramic greet sheet.

3. The method according to claim 2, wherein the heated green composite is sintered.

4. The method according to claim 3, wherein the distance between the conductive films of said pair of first green ceramic sheets in the green composite stack is about 0.3 to 1.2 μm.

5. The method according to claim 5, wherein the conductive films comprise nickel and have a thickness of about 0.1 to 0.8 μm, the first and second ceramics comprise the same dielectric barium titanate, and wherein the first and second ceramic green sheets have a thickness of at least about 0.1 μm.

6. The method according to claim 1, wherein the distance between the conductive films of said pair of first green ceramic sheets in the green composite stack is about 0.3 to 1.2 μm.

7. The method according to claim 1, further comprising forming a first ceramic green sheet by applying a slurry comprising the first ceramic green sheet ceramic material and binder to a thin film conductive film disposed on a carrier sheet to form a first ceramic green sheet layer having a first main surface with the conductive film disposed thereon and an opposing second main surface.

8. The method according to claim 7, wherein a second ceramic green sheet slurry comprising the second ceramic green sheet ceramic material and binder is applied to the opposing second main surface of the a first ceramic green sheet slurry layer to form a layer having one surface adjacent the second main surface of the first green sheet layer and an opposing second surface.

9. The method according to claim 8, wherein a slurry comprising the first ceramic green sheet ceramic material and binder is applied to the second surface of the second ceramic green sheet layer so as to form the other member of the pair of first ceramic green sheets.

10. The method according to claim 9, wherein a thin-film conductive film is provided on the first main surface of the other member of the pair of first ceramic green sheets.

11. A method for making a monolithic ceramic capacitor, comprising:
(a) preparing first ceramic green sheets each having a first main surface, the first ceramic green sheets comprising a first ceramic material powder and a first binder;
(b) forming a green composite comprising the following sequentially stacked layers: a thin-film conductive film, at least one first ceramic green sheet having its first main surface facing said film, at least one second ceramic green sheet, at least one first ceramic green sheet having its first main surface facing away form the second ceramic green sheet, and a thin-film conductive film, wherein the second ceramic green sheet comprise a second ceramic material powder and a second binder, and wherein the second ceramic green sheets is arranged so as not to come into contact with the first main surfaces of the first ceramic green sheets; and
(c) heating the green composite to remove the first binder and the second binder,
wherein the second binder is removed before the first binder is removed.

12. The method according to claim 11, wherein the content of the second binder relative to the second ceramic material powder is smaller than the content of the first binder relative to the first ceramic material powder.

13. The method according to claim 11, wherein the first ceramic green sheets with the conductive films are each prepared by transferring a conductive film disposed on a carrier film onto the first main surface of the first ceramic green sheet.

14. The method according to claim 11, wherein the first ceramic green sheets with the conductive films are each prepared by applying a ceramic slurry comprising the first ceramic material powder and the first binder on the conductive film disposed on a carrier film.

15. The method according to claim 11, wherein a first ceramic slurry comprising the first ceramic material powder and the first binder is applied on the conductive film disposed on a carrier film so as to form a first ceramic green sheet, and a second ceramic slurry comprising the second ceramic material powder and the second binder is applied on the first ceramic green sheet so as to form a second ceramic green sheet.

16. The method according to claim 11, wherein a first ceramic slurry comprising the first ceramic material powder and the first binder is applied on the conductive film disposed on a carrier film so as to form one of the first ceramic green sheets; a second ceramic slurry comprising the second ceramic material powder and the second binder is applied on the first ceramic green sheet so as to form a second ceramic green sheet; and a first ceramic slurry is applied on the second ceramic green sheet so as to form a ceramic green sheet.

17. The method according to claim 11, wherein the thickness of a dielectric layer disposed between the conductive films is about 0.3 to 1.2 μm.

18. The method according to claim 11, wherein the conductive film is formed by a thin-film forming method selected from the group consisting of vacuum vapor deposition, sputtering, electroplating and electroless plating.

19. The method according to claim 11, wherein the thickness of the conductive films is about 0.1 to 0.8 μm.

20. The method according to claim 11, wherein the conductive films comprise nickel and the first and second ceramics comprise the same dielectric barium titanate.
